(19) United States
(12) Patent Application Publication
(10) Pub. No.: US 2026/0238239 A1
(43) Pub. Date: Aug. 13, 2026

(54) DUAL MEMORY DIGITAL PREDISTORTION FOR DUAL CHAIN DOHERTY POWER AMPLIFIER

(71) Applicant: QUALCOMM Incorporated, San Diego, CA (US)

(72) Inventors: Ilia ANTSIFEROV, Netanya (IL); Guy WOLF, Rosh Haayin (IL); Ariel Yaakov SAGI, Haifa (IL); Evgeny LEVITAN, Haifa (IL)

(21) Appl. No.: 19/049,361

(22) Filed: Feb. 10, 2025

(51) Int. Cl. H04B 1/04; H03F 1/02; H03F 3/24

(52) U.S. Cl. CPC H04B 1/0475; H03F 1/0288; H03F 3/245; H03F 2200/451; H04B 2001/0425

(57) ABSTRACT

A transmitter including a carrier memory digital predistortion (DPD) circuit configured to predistort an input signal to generate a first carrier predistorted signal; a peaking memory digital predistortion (DPD) circuit configured to predistort the input signal to generate a first peaking predistorted signal; and a Doherty amplifier including a carrier power amplifier (CPA) and a peaking power amplifier (PPA), wherein the CPA is configured to generate a carrier transmit radio frequency (RF) signal based on the first carrier predistorted signal, and wherein the PPA is configured to generate a peaking transmit RF signal based on the first peaking predistorted signal.

### FIELD

This disclosure relates generally to transceivers and transmitters, and in particular, to a dual memory digital predistortion (DPD) for a dual chain Doherty power amplifier (PA).

### BACKGROUND

A transmitter or transceiver typically employs a power amplifier (PA) to amplify a radio frequency (RF) signal for wireless transmission to one or more remote wireless devices. The PA typically consumes significant power in performing the amplification. It is desirable for the PA to amplify the RF signal in a power efficient manner. Accordingly, some transmitters employ a Doherty PA to perform the RF signal amplification in a power efficient manner. Such Doherty PA uses a carrier power amplifier (CPA) to amplify the RF signal based on a lower dynamic power range of the RF signal, and a peaking power amplifier (PPA) based on a higher dynamic power range of the RF signal. Linear amplification of the RF signal by the Doherty PA is of interest.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to a transmitter. The transmitter includes: a carrier memory digital predistortion (DPD) circuit configured to predistort an input signal to generate a first carrier predistorted signal; a peaking memory digital predistortion (DPD) circuit configured to predistort the input signal to generate a first peaking predistorted signal; and a Doherty amplifier including a carrier power amplifier (CPA) and a peaking power amplifier (PPA), wherein the CPA is configured to generate a carrier transmit radio frequency (RF) signal based on the first carrier predistorted signal, and wherein the PPA is configured to generate a peaking transmit RF signal based on the first peaking predistorted signal.

Another aspect of the disclosure relates to a method of generating a transmit radio frequency (RF) signal. The method includes: applying a first memory predistortion to an input signal to generate a first carrier predistorted signal; applying a second memory predistortion to the input signal to generate a first peaking predistorted signal; generating a carrier radio frequency (RF) signal based on the first carrier predistorted signal; generating a peaking radio frequency (RF) signal based on the first peaking predistorted signal; amplifying the carrier RF signal to generate a carrier transmit RF signal; amplifying the peaking RF signal to generate a peaking transmit RF signal; and combining the carrier transmit RF signal and the peaking transmit RF signal to generate the transmit RF signal.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1 illustrates a block diagram of an example wireless communication system in accordance with an aspect of the disclosure.

FIG. 2 illustrates a block diagram of an example transceiver in accordance with another aspect of the disclosure.

FIG. 3A illustrates a block diagram of an example transmitter in accordance with another aspect of the disclosure.

FIG. 3B illustrates a graph depicting an output fundamental current versus an input voltage amplitude of a Doherty Amplifier of the transmitter of FIG. 2 in accordance with another aspect of the disclosure.

FIG. 4A illustrates a block diagram of another example transmitter in accordance with another aspect of the disclosure.

FIG. 4B illustrates a graph depicting gain profile versus input power of an example Doherty Amplifier of FIG. 4A in accordance with another aspect of the disclosure.

FIG. 4C illustrates a graph depicting a combined (peaking and carrier power amplifiers) gain profile versus input power including digital predistortion (DPD) signal associated with the example Doherty Amplifier of FIG. 4A in accordance with another aspect of the disclosure.

FIG. 4D illustrates a graph depicting separate gain profiles (peaking and carrier power amplifiers) versus input power including corresponding digital predistortion (DPD) signals associated with the example Doherty Amplifier of FIG. 4A in accordance with another aspect of the disclosure.

FIG. 5 illustrates a signal diagram of example signals associated with applying digital predistortion (DPD) in the example transmitter in accordance with another aspect of the disclosure.

FIG. 6 illustrates a signal diagram of example signals associated with applying digital predistortion (DPD) in the example transmitter in accordance with another aspect of the disclosure.

FIG. 7 illustrates a block diagram of another example transmitter in accordance with another aspect of the disclosure.

FIG. 8 illustrates a flow diagram of an example method of applying digital predistortion (DPD) in with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. The term “substantially” means that the associated parameter may not be exact as indicated but accounts for some variation due to specified tolerances.

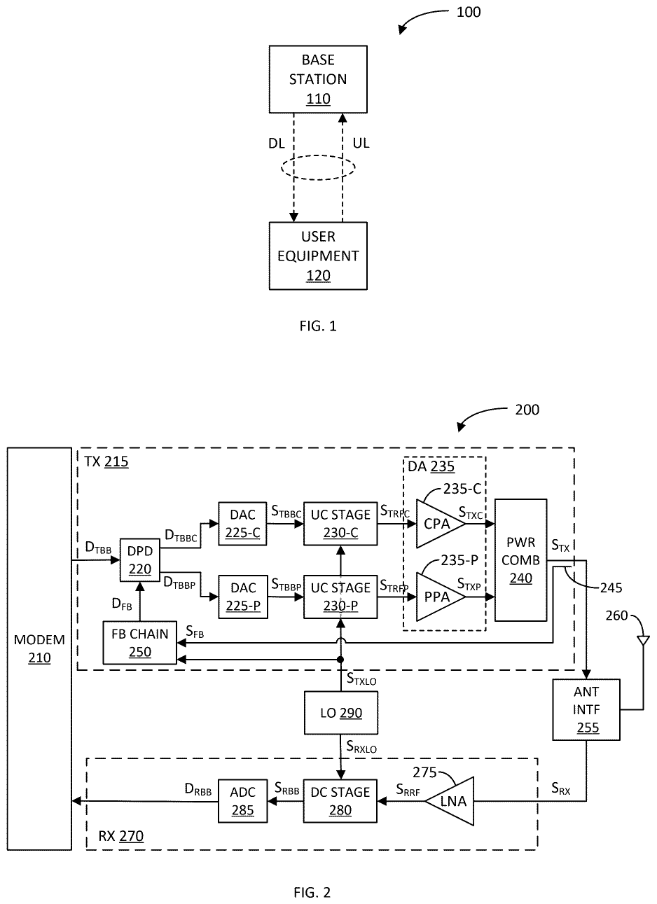

FIG. 1 illustrates a block diagram of an example wireless communication system 100 in accordance with an aspect of the disclosure. The wireless communication system 100 includes a base station (BS) 110 and a user equipment (UE) 120. The wireless communication system 100 may correspond to a wireless wide area network (WWAN) (e.g., a Fifth Generation (5G) or Sixth Generation (6G) New Radio (NR) WWAN or other), wireless local area network (WLAN) (e.g., WiFi or other), short range wireless area network (e.g., Bluetooth or other), a wireless personal area network (WPAN)), and/or other type of wireless network.

In this example, the base station (BS) 110 and the user equipment (UE) 120 wirelessly communicate with each other. For example, the base station (BS) 110 may transmit a downlink (DL) radio frequency (RF) signal to the user equipment (UE) 120. The user equipment (UE) 120, in turn, may transmit an uplink (UL) RF signal.

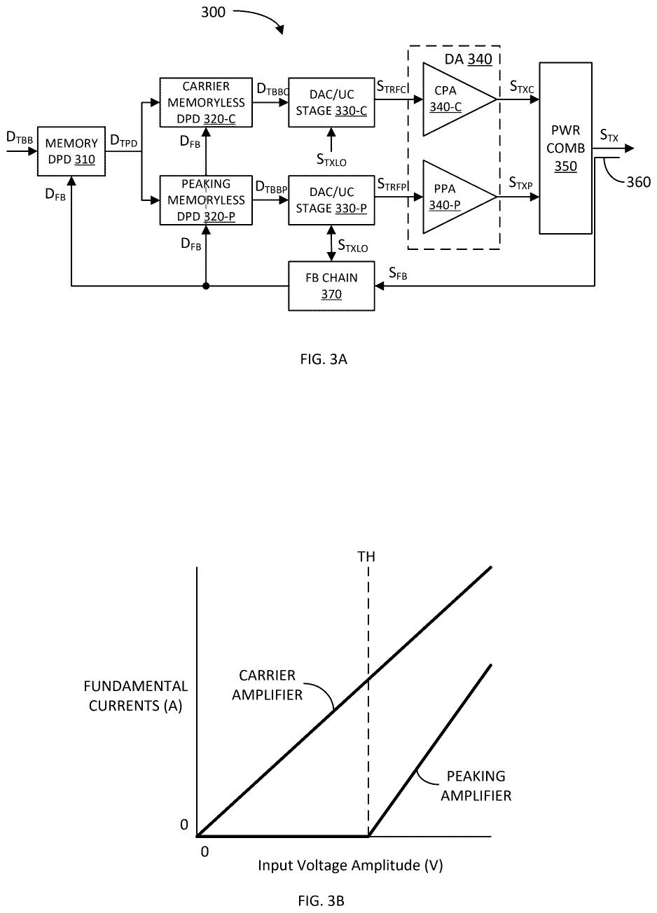

FIG. 2A illustrates a block diagram of an example transceiver 200 in accordance with another aspect of the disclosure. The transceiver 200 may be implemented in the base station (BS) 110 for transmission and reception of the DL RF signal and the UL RF signal, respectively. The transceiver 200 may also be implemented in the user equipment (UE) 120 for transmission and reception of the UL RF signal and the DL RF signal, respectively. In particular, the transceiver 200 includes a modem 210 (e.g., a baseband processing circuit), a transmitter 215, an antenna interface 255, an antenna (e.g., an antenna array) 260, a receiver 270, and a local oscillator (LO) 290.

The transmitter 215, in turn, may be implemented in a dual channel (carrier and peaking transmit chains) of a Doherty amplifier 235. That is, the transmitter 215 includes a digital predistortion (DPD) circuit 220 common to the dual channel of the Doherty amplifier 235. The carrier transmit chain includes a digital-to-analog converter (DAC) 225-C, a frequency upconverting (UC) stage 230-C, and a carrier power amplifier (CPA) 235-C. The peaking chain includes a DAC 225-P, a frequency upconverting (UC) stage 230-P, and a peaking power amplifier (PPA) 235-P. The transmitter 215 includes a power combiner 240, a coupler 245, and a feedback (FB) downconverting stage 250 common to the dual channel Doherty amplifier 235. The receiver 270, in turn, includes a low noise amplifier (LNA) 275, a frequency downconverting (DC) stage 280, and an analog-to-digital converter (ADC) 285.

With regard to signal transmission, the modem 210 is configured to generate a digital transmit baseband signal D_{TBB}. The DPD 220 is configured to apply digital predistortion (DPD) to the digital transmit baseband signal D_{TBB} based on a feedback signal DFB to generate a digital carrier transmit baseband signal D_{TBBC} and a digital peaking transmit baseband signal D_{TBBP}. The carrier DAC 225-C is configured to convert the digital carrier transmit baseband signal D_{TBBC} into an analog carrier transmit baseband signal S_{TBBC}. The carrier frequency upconverting (UC) stage 230-C (which may include one or more cascaded UC stages) is configured to frequency upconvert the analog carrier transmit baseband signal S_{TBBC} into a carrier transmit radio frequency (RF) signal S_{TRFC} based on a transmit local oscillator (LO) signal S_{TXLO} generated by the LO 290. The CPA 235-C is configured to power amplify the carrier transmit RF signal S_{TRFC} to generate a carrier transmit signal S_{TXC}.

The peaking DAC 225-P, when enabled, is configured to convert the digital peaking transmit baseband signal D_{TBBP} into an analog peaking transmit baseband signal S_{TBBP}. The peaking frequency upconverting (UC) stage 230-P (which may include one or more cascaded UC stages) is configured to frequency upconvert the analog peaking transmit baseband signal S_{TXBP} into a peaking transmit RF signal S_{TRFP} based on the transmit LO signal S_{TXLO} generated by the LO 290. The PPA 235-P is configured to power amplify the peaking transmit RF signal S_{TRFP} to generate a peaking transmit signal S_{TXP}. The power combiner 240 is configured to combine the carrier and peaking transmit RF signals S_{TRFC} and STREP to generate a transmit RF signal S_{TX}.

The transmit RF signal S_{TX} is provided to the antenna interface (e.g., diplexer, duplexer, switch, etc.) 255, which, in turn, provides it to the antenna 260 for wireless transmission (e.g., as a DL RF signal if the transceiver 200 is implemented in a base station (BS) or a UL RF signal if the transceiver 200 is implemented in a user equipment (UE)). The coupler 245 is configured to couple out a portion sample of the transmit RF signal S_{TX} to provide a feedback RF signal S_{FB} to the FB chain 250. The FB chain 250 is configured to frequency downconvert (based on the transmit LO signal S_{TXLO}) the feedback RF signal S_{FB} and digitize the downconverted signal to generate the digital feedback signal DFB. As mentioned, the DPD circuit 220 is configured to apply digital predistortion to the digital baseband signal D_{TBB} based on the digital feedback signal DFB.

With regard to signal reception, the antenna 260 is configured to pickup/sense a wireless RF signal and provide it to an input of the LNA 275 as a received RF signal S_{RX}. The LNA 275 is configured to amplify the received RF signal S_{RX} to generate an amplified received RF signal S_{RRF}. The downconverting (DC) stage 280 (which may include one or more cascaded DC stages) is configured to downconvert the received RF signal S_{RRF} into a received analog baseband signal S_{RBB} based on a received LO signal S_{RXLO} generated by the LO 290. The ADC 285 is configured to convert the received analog baseband signal S_{RBB} into a received digital baseband signal D_{RBB}. The modem 210 is configured to receive and process the received digital baseband signal D_{RBB} to extract any information/data therein.

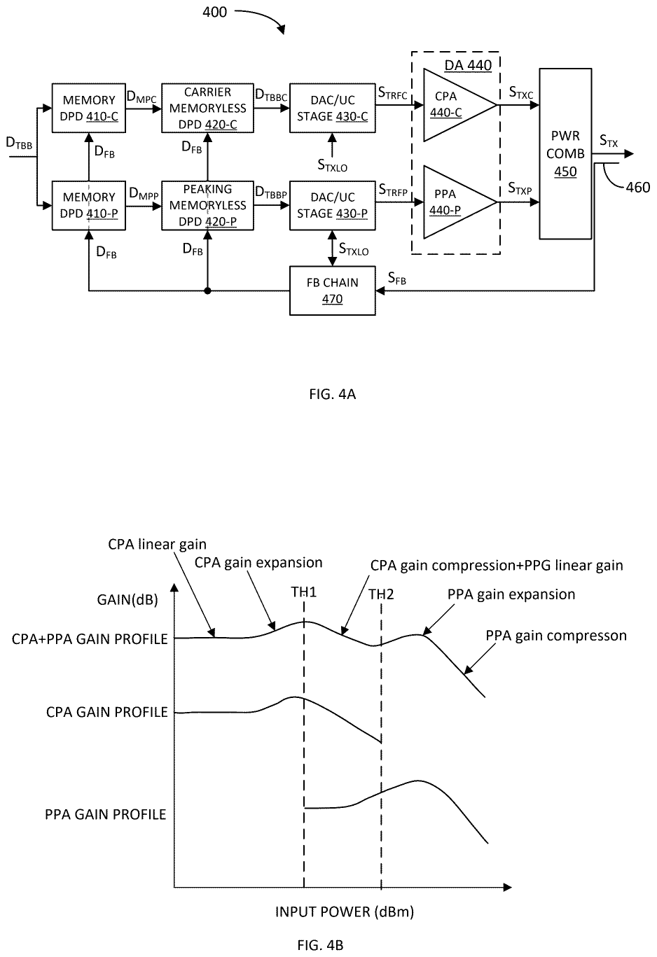

FIG. 3A illustrates a block diagram of an example transmitter 300 in accordance with another aspect of the disclosure. The transmitter 300 may be an example more detailed implementation of the transmitter 215 of transceiver 200. The transmitter 300 includes a memory DPD circuit 310 common to both carrier and peaking transmit chains. The carrier transmit chain includes a carrier memoryless (e.g., look-up table (LUT)-based) DPD circuit 320-C, a DAC/UP stage 330-C, and a carrier power amplifier (CPA) 340-C. The peaking transmit chain includes a peaking memoryless (e.g., LUT-based) DPD circuit 320-P, a DAC/UP stage 330-P, and a peaking power amplifier (PPA) 340-P. The power combiner 350, coupler 360, and feedback (FB) chain 370 are common to both the carrier and peaking chains.

The memory DPD circuit 310 is configured to apply memory and residual predistortion to the digital transmit baseband signal D_{TBB} to generate a digital transmit predistorted signal D_{TPD} based on a digital feedback signal DFB generated by the FB chain 370. The memory predistortion is based on a current sample and a set of one or more previous samples of the digital baseband signal D_{TBB}. This is because the nonlinearity characteristics of the CPA 340-C and the PPA 340-P vary depending on the current and prior samples of the carrier transmit RF signal S_{TRFC} and the peaking transmit RF signal STREP, respectively. The residual predistortion is based on some residual non-linearity left over from the predistortion applied by the carrier and peaking memoryless DPD circuits 320-C and 320-P, respectively.

With regard to the carrier chain, the carrier memoryless DPD circuit 320-C is configured to apply memoryless predistortion to the digital transmit predistorted signal D_{TPD} based on the digital feedback signal DFB to generate a carrier transmit baseband signal D_{TBBC}. The memoryless predistortion is based on the current sample (not previous samples) of the digital transmit predistorted signal D_{TPD}. The carrier DAC/UC stage 330-C is configured to collectively convert the digital carrier transmit signal D_{TBBC} into a carrier transmit RF signal S_{TRFC} based on a transmit LO signal S_{TXLO}. The CPA 340-C is configured to power amplify the carrier transmit RF signal S_{TRFC} to generate a carrier transmit signal S_{TXC}.

With regard to the peaking chain, the peaking memoryless DPD circuit 320-P is configured to apply memoryless predistortion to the digital transmit predistorted signal D_{TPD} based on the digital feedback signal DFB to generate a peaking transmit baseband signal D_{TBBP}. The memoryless predistortion is based on the current sample (not previous samples) of the digital transmit predistorted signal D_{TPD}. The peaking DAC/UC stage 330-P is configured to convert the digital peaking transmit signal D_{TBBP} into a peaking transmit RF signal STREP based on the transmit LO signal S_{TXLO}. The PPA 340-P is configured to power amplify the peaking transmit RF signal STREP to generate a peaking transmit signal S_{TXP}.

The power combiner 350 is configured to combine the carrier and peaking transmit RF signals S_{TXC} and S_{TXP} to generate a transmit RF signal S_{TX} for wireless transmission. The coupler 360 is configured to couple out a portion of the transmit RF signal S_{TX} to generate a feedback RF signal S_{FB}. The FB chain 370 is configured to frequency downconvert the feedback RF signal S_{FB} based on the transmit LO signal S_{TXLO}, and digitized the downconverted signal to generate the digital feedback signal DFB. As discussed, the memory DPD circuit 310, the carrier memoryless DPD circuit 320-C, and the peaking memoryless DPD circuit 320-P use the digital feedback signal DFB to apply their respective predistortions on the signals D_{TBB}, D_{TPD}, and D_{TPD}, respectively.

FIG. 3B illustrates a graph depicting an output fundamental current versus an input voltage amplitude of a Doherty Amplifier CPA 340-C and PPA 340-P in accordance with another aspect of the disclosure. The horizontal axis represents input voltage amplitude in Volts (V) at the inputs of the CPA 340-C and PPA 340-P. The vertical axis represents the fundamental currents in Amperes (A) at the outputs of the inputs of the CPA 340-C and PPA 340-P.

As indicated, the CPA 340-C, and not the PPA 340-P, amplify the carrier input signal S_{TRFC} with an input voltage amplitude between zero (0) and a threshold (TH) voltage amplitude to generate the fundamental current of the carrier output signal S_{TXC}. When the input amplitude voltage of the input signal S_{TRFC} exceeds the threshold (TH), both the CPA 340-C and PPA 340-P amplify the carrier and peaking input signals S_{TRFC} and S_{TRFP} to generate the fundamental currents of the carrier and peaking output signals S_{TXC} and S_{TXP}, respectively.

Note that the linearity or non-linearity characteristics of the CPA 340-C and the PPA 340-P may be different (e.g., different slopes and non-linearity characteristics). As such, the memory DPD circuit 310 being common to both the CPA 340-C and PPA 340-P may not optimally memory predistort the digital baseband signal D_{TBB} to generate the predistorted signal D_{TPD} for optimal performance for both the carrier and peaking transmit signals S_{TXC} and S_{TXP}. In other words, the memory DPD circuit 310 may perform a compromised memory predistortion that that may be good for both the CPA 340-C and the PPA 340-P, but not necessarily optimal for both CPA 340-C and the PPA 340-P.

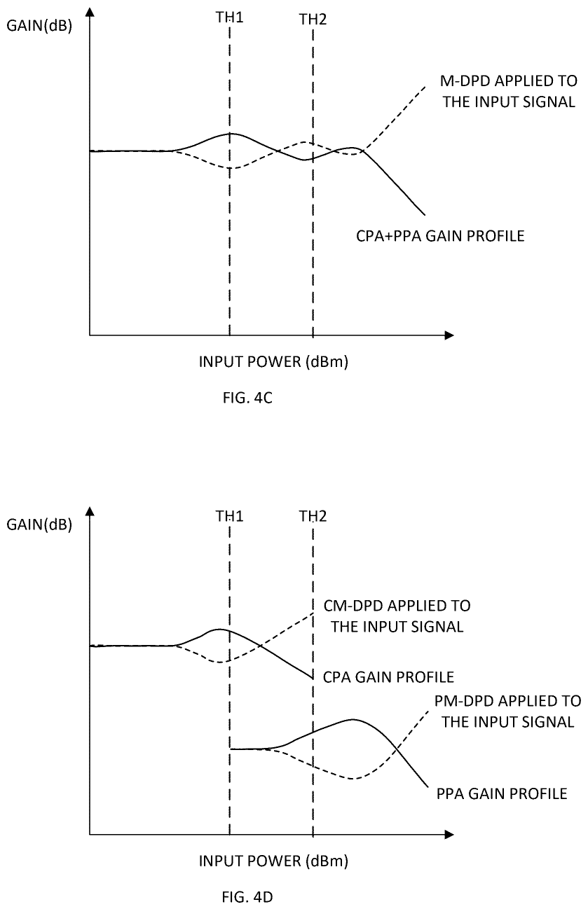

FIG. 4A illustrates a block diagram of an example transmitter 400 in accordance with another aspect of the disclosure. The transmitter 400 is similar to transmitter 300 including many of the same elements as indicated by the same reference numbers with the exception that their most significant digit is a “4” for transmitter 400 instead of a “3” for transmitter 300.

The transmitter 400 differs from transmitter 300 in that the transmitter 400 includes separate memory DPD circuits 410-C and 410-P for the carrier transmit chain and the peaking transmit chain, respectively. That is, the carrier memory DPD circuit 410-C is configured to apply memory and residual DPD on the input digital baseband signal D_{TBB} to generate a carrier memory predistorted signal D_{MPC} based on a digital feedback signal DFB. The peaking memory DPD circuit 410-P is configured to apply memory and residual DPD on the input digital baseband signal D_{TBB} to generate a peaking memory predistorted signal D_{MPP}.

The carrier memoryless DPD circuit 420-C is configured to apply memoryless DPD to the carrier memory predistorted signal D_{MPC} based on the digital feedback signal DFB to generate a carrier transmit baseband signal D_{TBBC}. The peaking memoryless DPD circuit 420-P is configured to apply memoryless DPD to the peaking memory predistorted signal D_{MPP} based on the digital feedback signal DFB to generate a peaking transmit baseband signal D_{TBBP}.

The carrier DAC/UC stage 430-C is configured to convert the digital carrier transmit baseband signal D_{TBBC} into a carrier transmit RF signal S_{TRFC} based on a transmit LO signal S_{TXLO}. The CPA 440-C is configured to power amplify the carrier transmit RF signal S_{TRFC} to generate a carrier transmit signal S_{TXC}. The peaking DAC/UC stage 430-P is configured to convert the digital peaking transmit baseband signal D_{TBBP} into a peaking transmit RF signal STREP based on the transmit LO signal S_{TXLO}. The PPA 440-P is configured to power amplify the peaking transmit RF signal STREP to generate a carrier transmit signal S_{TXP}.

The power combiner 450 is configured to combine the carrier and peaking transmit RF signals S_{TXC} and S_{TXP} to generate a transmit RF signal S_{TX} for wireless transmission. The coupler 460 is configured to couple out a portion of the transmit RF signal S_{TX} to generate a feedback RF signal S_{FB}. The FB chain 470 is configured to frequency downconvert the feedback RF signal S_{FB} based on the transmit LO signal S_{TXLO}, and digitized the downconverted signal to generate the digital feedback signal DFB.

FIG. 4B illustrates a graph depicting gain profile versus input power of CPA 440-C and PPA 440-P of the dual chain Doherty Amplifier in accordance with another aspect of the disclosure. The horizontal axis represents input power in decibel milliWatt (dBm) of the signals S_{TRFC} and STREP of the CPA 440-C and PPA 440-P, respectively. The vertical axis represents the gain profiles in decibel (dB) of the CPA 440-C and the PPA 440-P, and the combined gain profile of both the CPA 440-C and the PPA 440-P.

As indicated, the CPA 440-C has a gain profile characterized with a linear gain region, an expansion gain region, and a gain compression region. Similarly, the PPA 440-P has a gain profile characterized with a linear gain region, an expansion gain region, and a gain compression region. Below a first threshold input power TH1, the CPA 440-C amplifies the input signal S_{TRFC} in accordance with its linear gain region and its gain expansion region. Below the first threshold input power TH1, the PPA 440-P may not be active. Between the first threshold input power TH1 and the second threshold input power TH2, the CPA 440-C amplifies its input signal S_{TRFC} in accordance with its gain compression region and the PPA 440-P amplifies its input signal STREP in accordance with its linear gain region. Above the second threshold input power TH2, the PPA 440-C amplifies the input signal STREP in accordance with its gain compression and gain expansion regions. Above the second threshold input power TH2, the CPA 440-C may not be active. The combined gain profile for the dual chain Doherty amplifier is shown with the various regions.

FIG. 4C illustrates a graph depicting a combined (peaking and carrier power amplifiers) gain profile versus input power including digital predistortion (DPD) signal associated with the example Doherty Amplifier in accordance with another aspect of the disclosure. The solid line represents the combined gain profile for the CPA 340-C and the PPA 340-P. The dashed line if the predistortion applied by the DPD circuits 310/320-C/320-P of transmitter 300.

That is, the DPD circuits 310/320-C/320-P predistort the input digital signal D_{TBB} with a gain profile substantially opposite the combined gain profile for the CPA 440-C and the PPA 440-P. Thus, in the linear gain region of the CPA 340-C, the DPD circuits 310/320-C/320-P do not predistort the input digital signal D_{TBB} as the combined gain profile is linear in that region. In the gain expansion region of the CPA 340-C, the DPD circuits 310/320-C/320-P predistort the input digital signal D_{TBB} by reducing its power substantially opposite to the gain expansion region of the CPA 340-C.

In the gain compression region of the CPA 340-C and the linear region of the PPA 340-P, the DPD circuits 310/320-C/320-P predistort the input digital signal D_{TBB} by increasing its power substantially opposite to the gain compression region of the CPA 340-C. In the gain expansion region of the PPA 340-P, the DPD circuits 310/320-C/320-P predistort the input digital signal D_{TBB} by reducing its power substantially opposite to the gain expansion region of the PPA 340-P. In the gain compression region of the PPA 340-P, the DPD circuits 310/320-C/320-P predistort the input digital signal D_{TBB} by increasing its power substantially opposite to the gain compression region of the PPA 340-P. As the memory DPD circuit 310 is dealing with two different gain profiles for the CPA 440-C and PPA 440-P, it may be difficult for the memory DPD circuit 310 to apply accurate predistortion so as to achieve linearity.

FIG. 4D illustrates a graph depicting separate gain profiles (peaking and carrier power amplifiers) versus input power including corresponding digital predistortion (DPD) signals associated with the example Doherty Amplifier in accordance with another aspect of the disclosure. The solid lines represent the gain profiles of the CPA 440-C and the PPA 440-P. The dashed lines represent the predistortion applied by the carrier memory DPD circuit 410-C/memoryless DPD circuit 420-C and the peaking memory DPD circuit 410-P/memoryless DPD circuit 420-P of transmitter 400.

That is, the carrier memory DPD circuit 410-C and carrier memoryless DPD predistort the input digital signal D_{TBB} with a gain profile substantially opposite the gain profile of the CPA 440-C. Thus, in the linear gain region of the CPA 440-C, the DPDs 410-C/420-C do not predistort the input digital signal D_{TBB} as the gain profile is linear in that region. In the gain expansion region of the CPA 440-C, the DPDs 410-C/420-C predistort the input digital signal D_{TBB} by reducing its power substantially opposite to the gain expansion region of the CPA 440-C. In the gain compression region of the CPA 440-C, the DPDs 410-C/420-C predistort the input digital signal D_{TBB} by increasing its power substantially opposite to the gain compression region of the CPA 440-C.

The peaking memory DPD circuit 410-P and the peaking memoryless DPD 420-P predistort the input digital signal D_{TBB} with a gain profile substantially opposite the gain profile of the PPA 440-P. Thus, in the linear gain region of the PPA 440-P, the DPDs 410-P/420-P do not predistort the input digital signal D_{TBB} as the gain profile is linear in that region. In the gain expansion region of the PPA 440-P, the DPDs 410-P/420-P predistort the input digital signal D_{TBB} by reducing its power substantially opposite to the gain expansion region of the PPA 440-P. In the gain compression region of the PPA 440-P, the DPDs 410-P/420-P predistort the input digital signal D_{TBB} by increasing its power substantially opposite to the gain compression region of the PPA 440-P. As the carrier and peaking memory DPD circuits 410-C and 410-P perform separate predistortion for the CPA 440-C and PPA 440-P, a more accurate predistortion and linearization of the Doherty amplifier 440 may be achieved as compared to the DPD 310 common to both carrier and peaking chains.

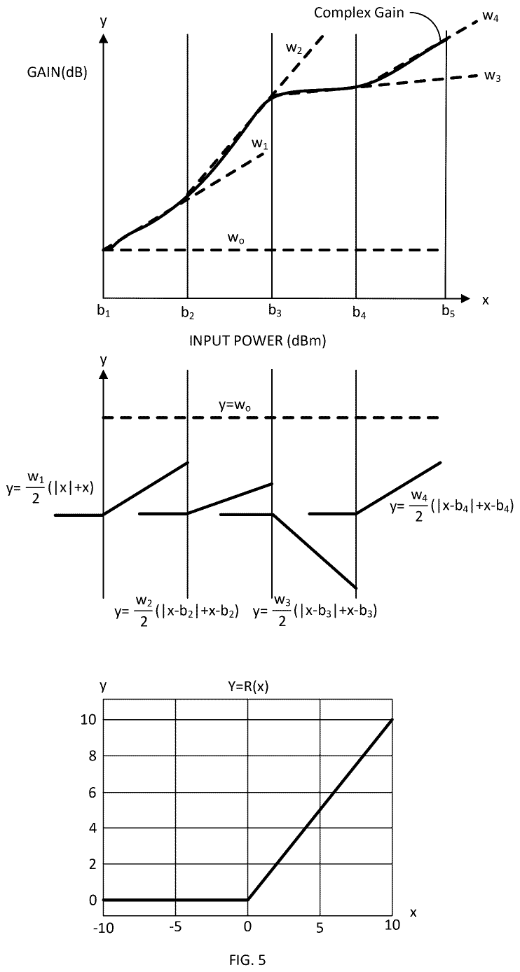

FIG. 5 illustrates a signal diagram of example signals associated with applying digital predistortion (DPD) in the example transmitter 400 in accordance with another aspect of the disclosure. The memory DPD circuits 410-C and 410-P and/or memoryless DPDs circuits 420-C and 420-P may perform piecewise linear (PWL) for linearizing the Doherty amplifier 440.

The top graph in FIG. 5 represents the complex gain profile (gain versus input power) of either the CPA 440-C or PPA 440-P. The gain profile includes a set of four (4) gain segments. The gain profile begins at an initial gain value of w₀ at input power level b₁. A first gain segment between input power levels b₁ and b₂ is characterized as having a substantially linear gain with a slope represented by w₁. A second gain segment between input power levels between b₂ and b₃ is characterized as having a gain expansion with a slope represented by w₂ greater than w₁. A third gain segment between input power levels b₃ and b₄ is characterized as having a gain compression with a slope represented by w₃ less than w₂. A fourth gain segment between input power levels b₄ and b₅ is characterized as having a gain expansion with a slope represented by w₄ greater than w₃.

Each of the DPDs may approximate the aforementioned gain profile in accordance with the following PWL relationship:

$$y or G ( x ) = {w}_{0} + {\sum }_{k = 1}^{K} {w}_{k} R ( x - {b}_{k} ) \qquad Eq . 1$$

Where y or G(x) is the gain profile of the CPA 440-C or PPA 440-P, k is the gain profile segment for a set of K segments, bₖ is the power level at the beginning of the kth segment, wₖ is the slope of the gain profile for the kth segment, and x is the power level of the input signal to the CPA 440-C or PPA 440-P. R(x) is the rectified linear unit (ReLU) function characterized as being zero (0) below a power level x equal to or less than zero (0) (e.g., R(x≤0)=0) and a slope of one (1) for a power level x above zero (0) (e.g., R(x>0)=x). As illustrated in the lower graph of FIG. 5, the ReLU function may be represented as follows:

$$R ( x ) = \frac{1}{2} ( \vert x \vert + x ) = \{ \begin{matrix}0 , x \leq 0 \\ x , x > 0\end{matrix} \qquad Eq . 2$$

Thus, the four (4) gain profile segments may be respectively approximated as follows:

$$y or G ( x ) = \frac{{w}_{1}}{2} ( \vert x \vert + x ) \qquad Eq . 3 a$$

$$y or G ( x ) = \frac{{w}_{2}}{2} ( \vert x - {b}_{2} \vert + x - {b}_{2} ) \qquad Eq . 3 b$$

$$y or G ( x ) = \frac{{w}_{3}}{2} ( \vert x - {b}_{3} \vert + x - {b}_{3} ) \qquad Eq . 3 c$$

$$y or G ( x ) = \frac{{w}_{4}}{2} ( \vert x - {b}_{4} \vert + x - {b}_{4} ) \qquad Eq . 3 d$$

The aforementioned ReLU segments are depicted in the middle graph in FIG. 5. Any of the DPDs described herein may use such PWL to characterize the gain profile of the CPA 440-C or PPA 440-P based on the sum of the gain segments, and apply the corresponding predistortion.

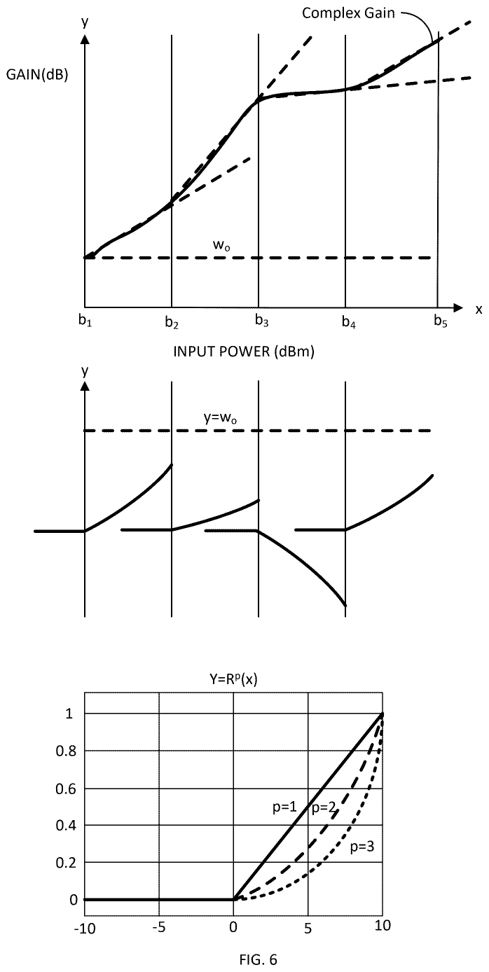

FIG. 6 illustrates a signal diagram of example signals associated with applying digital predistortion (DPD) in the example transmitter 400 in accordance with another aspect of the disclosure. The memory DPD circuits 410-C and 410-P and/or memoryless DPD circuits 420-C and 420-P may perform piecewise polynomial (PWP) approximation of the gain profiles of the CPA 440-C and 440-P for linearizing the Doherty power amplifiers. The bottom of the diagram represents the rectified polynomial function R^{p}(x). The polynomial function R^{p}(x) may be represented as follows:

$${R}^{p} ( x ) = \frac{1}{2} {( \vert x \vert + x )}^{p} = \{ \begin{matrix}0 , x \leq 0 \\ {x}^{p} , x > 0\end{matrix} \qquad Eq . 4$$

That is, the rectified polynomial function R^{p}(x) is the same as the ReLU for a p value of one (1). That is, the R¹(x) is the rectified linear unit (ReLU) function characterized as being zero (0) below a power level x equal to or less than zero (0) (e.g., R¹(x≤0)=0) and a slope of one (1) for a power level x above zero (0) (e.g., R¹(x>0)=x). The R²(x) function is characterized as being zero (0) below a power level x equal to or less than zero (0) (e.g., R²(x≤0)=0) and a non-linear slope with a power of two (2) for power level x above zero (0) (e.g., R²(x>0)=x²). The R³(x) function is characterized as being zero (0) below a power level x equal to or less than zero (0) (e.g., R³(x≤0)=0) and a non-linear slope with the power of three (3) for power level x above zero (0) (e.g., R³(x>0)=x³).

Accordingly, the gain profile of the CPA 440-C or PPA 440-P may be approximated as follows:

$$y or G ( x ) = {w}_{0} + {\sum }_{p = 1}^{P} {\sum }_{k = 1}^{K} {w}_{pk} {R}^{P} ( x - {b}_{k} ) \qquad Eq . 5$$

As illustrated in the middle diagram of FIG. 6, the four (4) gain segments have a non-linear approximation of the gain profile of the CPA 440-C or PPA 440-P. Any of the DPDs may use PWP approximation of the gain profile of the CPA 440-C or PPA 440-P to apply its DPD on the corresponding input signal.

As the memory DPD circuits 410-C and 410-P perform DPD over a set of n−1 samples (where the current sample is denoted as “n” and previous sample are denoted as “1”) of the corresponding input signals, the memory DPD circuits 410-C and 410-P may perform its memory DPD circuits in accordance with a Volterra series with the following generalized memory polynomial (GMP) relationship:

$$y = {\sum }_{m ∈ M} {x}_{n - m} ( {w}_{m} + {\sum }_{l ∈ L} {\sum }_{p = 1}^{P} {\sum }_{k = 1}^{K} {w}_{lpk} {R}^{P} ( \vert {x}_{n - l \vert} - {b}_{k} )$$

Where k is the polynomial order, l is the memory lag, and m is Volterra kernel order, wₗₚₖ is the weight, bₖ is the beginning of the segment, R^{p} is the piecewise polynomial (PWP).

Training can be done per carrier or peaking amplifier using direct/indirect least squares learning algorithms in simultaneous or separate fashion and usually will be applied sequentially to obtain memory DPD and memoryless DPD parameters in the cascade. Alternatively training similar to Neural Networks can be implemented where back propagation propagates the error backwards and calculates the gradient per each error, then using gradient descent, minimum of the target cost function using derivatives calculated during the back-propagation can be reached. Gradient descent (GD) based training done for memory DPD circuit and memoryless DPD circuit for carrier chain and separately for memory DPD circuit and memoryless DPD circuit for peaking chain can help to achieve the global minimum of target cost function and obtain best possible linearization performance for dual chain Doherty amplifier.

Training of carrier and peaking amplifier CPA 440-C and 440-P can be done together or separately, where the latter DPD training option may enable better performance. Training may be done sequentially for the memoryless DPD circuits 420-C and 420-P and afterwards for memory DPD circuits 410-C and 410-P separately for carrier/peaking chains. Optionally gradient descent (GD) method for training may be utilized.

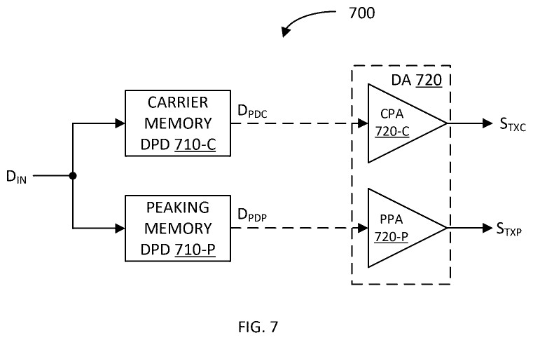

FIG. 7 illustrates a block diagram of another example transmitter 700 in accordance with another aspect of the disclosure. The transmitter 700 includes a carrier memory digital predistortion (DPD) circuit 710-C configured to predistort an input signal DIN to generate a first carrier predistorted signal D_{PDC}. The transmitter 700 further includes a peaking memory digital predistortion (DPD) circuit 710-P configured to predistort the input signal DIN to generate a first peaking predistorted signal D_{PDP}. Additionally, the transmitter 700 further includes a Doherty amplifier 720 including a carrier power amplifier (CPA) 720-C and a peaking power amplifier (PPA) 720-P. The CPA 700-C is configured to generate a carrier transmit radio frequency (RF) signal S_{TXC} based on the first carrier predistorted signal D_{PDC}. The PPA 720-P is configured to generate a peaking transmit RF signal S_{TXP} based on the first peaking predistorted signal D_{PDP}.

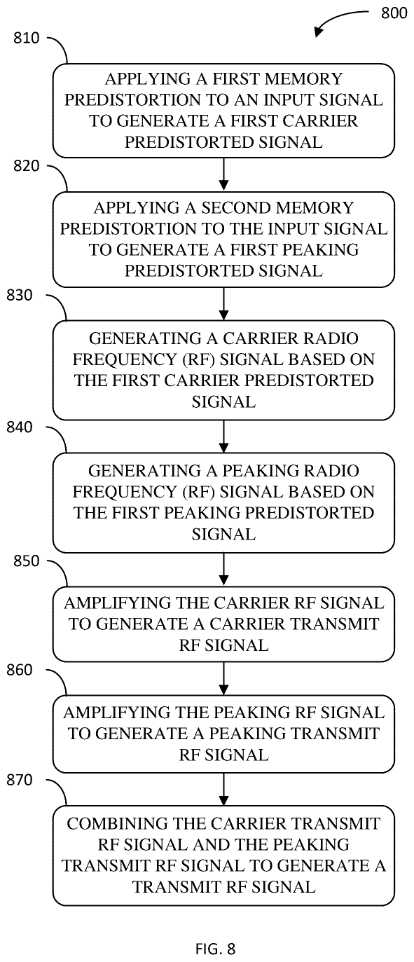

FIG. 8 illustrates a flow diagram of an example method 800 of generating a radio frequency (RF) transmit signal in with another aspect of the disclosure. The method 800 includes applying a first memory predistortion to an input signal to generate a first carrier predistorted signal (block 810). Examples of a means for applying a first memory predistortion to an input signal to generate a first carrier predistorted signal include any of the carrier memory DPD circuits described herein. The method 800 further includes applying a second memory predistortion to the input signal to generate a first peaking predistorted signal (block 820). Examples of means for applying a second memory predistortion to the input signal to generate a first peaking predistorted signal include any of the peaking memory DPD circuits described herein.

The method 800 further includes generating a carrier radio frequency (RF) signal based on the first carrier predistorted signal (block 830). Examples of means for generating a carrier radio frequency (RF) signal based on the first carrier predistorted signal include any of the carrier DAC/UC stages described herein. Additionally, the method 800 includes generating a peaking radio frequency (RF) signal based on the first peaking predistorted signal (block 840). Examples of means for generating a peaking radio frequency (RF) signal based on the first peaking predistorted signal include any of the carrier DAC/UC stages described herein.

Further, the method 800 includes amplifying the carrier RF signal to generate a carrier transmit RF signal (block 850). Examples of means for amplifying the carrier RF signal to generate a carrier transmit RF signal include any of the CPAs described herein. Additionally, the method 800 includes amplifying the peaking RF signal to generate a peaking transmit RF signal (block 860). Examples of means for amplifying the peaking RF signal to generate a peaking transmit RF signal include any of the PPAs described herein. And, the method 800 includes combining the carrier transmit RF signal with the peaking transmit RF signal to generate the transmit RF signal (block 870). Examples of means for combining the carrier transmit RF signal with the peaking transmit RF signal to generate a transmit RF signal include any of the power combiners described herein.

The following provides an overview of aspects of the present disclosure:
Aspect 1: A transmitter, comprising: a carrier memory digital predistortion (DPD) circuit configured to predistort an input signal to generate a first carrier predistorted signal; a peaking memory digital predistortion (DPD) circuit configured to predistort the input signal to generate a first peaking predistorted signal; and a Doherty amplifier including a carrier power amplifier (CPA) and a peaking power amplifier (PPA), wherein the CPA is configured to generate a carrier transmit radio frequency (RF) signal based on the first carrier predistorted signal, and wherein the PPA is configured to generate a peaking transmit RF signal based on the first peaking predistorted signal.
Aspect 2: The transmitter of aspect 1, wherein the carrier memory DPD circuit is configured to predistort the input signal based on a piecewise linear (PWL) approximation of a gain profile of the CPA.
Aspect 3: The transmitter of aspect 2, wherein the PWL approximation employs a rectified linear unit (ReLU) function that approximates a set of gain segments of the gain profile of the CPA.
Aspect 4: The transmitter of any one of aspects 1-3, wherein the peaking memory DPD circuit is configured to predistort the input signal based on a piecewise linear (PWL) approximation of a gain profile of the PPA.
Aspect 5: The transmitter of aspect 4, wherein the PWL approximation employs a rectified linear unit (ReLU) function that approximates a set of gain segments of the gain profile of the PPA.
Aspect 6: The transmitter of any one of aspects 1-5, wherein the carrier memory DPD circuit is configured to predistort the input signal based on a piecewise polynomial (PWP) approximation of a gain profile of the CPA.
Aspect 7: The transmitter of aspect 6, wherein the PWP approximation employs a rectified polynomial function that approximates a set of gain segments of the gain profile of the CPA.
Aspect 8: The transmitter of any one of aspect 1-7, wherein the peaking memory DPD circuit is configured to predistort the input signal based on a piecewise polynomial (PWP) approximation of a gain profile of the PPA.
Aspect 9: The transmitter of aspect 8, wherein the PWP approximation employs a rectified polynomial function that approximates a set of gain segments of the gain profile of the PPA.
Aspect 10: The transmitter of any one of aspects 1-9, further comprising: a carrier memoryless DPD circuit configured to predistort the first carrier predistorted signal to generate a second carrier predistorted signal, wherein the CPA is configured to generate the carrier transmit radio frequency (RF) signal based on the second carrier predistorted signal; and a peaking memoryless DPD circuit configured to predistort the first peaking predistorted signal to generate a second peaking predistorted signal, wherein the PPA is configured to generate the peaking transmit radio frequency (RF) signal based on the second peaking predistorted signal.
Aspect 11: The transmitter of aspect 10, wherein: the carrier memoryless DPD circuit is configured to predistort the first carrier predistorted signal based on a carrier lookup table (LUT); and the peaking memoryless DPD circuit is configured to predistort the first peaking predistorted signal based on a peaking lookup table (LUT).
Aspect 12: The transmitter of aspect 10 or 11, further comprising: a carrier digital-to-analog converter (DAC) configured to convert the second carrier predistorted signal into a carrier analog signal; a carrier frequency upconverter configured to frequency upconvert the carrier analog signal to generate a carrier radio frequency (RF) signal, wherein the CPA is configured to amplify the carrier RF signal to generate the carrier transmit RF signal; a peaking digital-to-analog converter (DAC) configured to convert the second peaking predistorted signal into a peaking analog signal; and a peaking frequency upconverter configured to frequency upconvert the peaking analog signal to generate a peaking radio frequency (RF) signal, wherein the PPA is configured to amplify the peaking RF signal to generate the peaking transmit RF signal.
Aspect 13: The transmitter of aspect 12, further comprising: a power combiner configured to combine the carrier transmit RF signal and the peaking transmit RF signal to generate a transmit RF signal; a coupler configured to couple out a portion of the transmit signal to generate a feedback RF signal; and a feedback chain configured to generate a digital feedback baseband signal based on the feedback RF signal, wherein the carrier memory DPD circuit is configured to predistort the input signal to generate the first carrier predistorted signal based on the digital feedback baseband signal, and wherein the peaking memory DPD circuit is configured to predistort the input signal to generate the first peaking predistorted signal based on the digital feedback baseband signal.
Aspect 14: The transmitter of any one of aspects 1-12, further comprising: a power combiner configured to combine the carrier transmit RF signal and the peaking transmit RF signal to generate a transmit RF signal; a coupler configured to couple out a portion of the transmit signal to generate a feedback RF signal; and a feedback chain configured to generate a digital feedback baseband signal based on the feedback RF signal.
Aspect 15: The transmitter of any one of aspects 1-13, further comprising: a power combiner configured to combine the carrier transmit RF signal and the peaking transmit RF signal to generate a transmit RF signal; an antenna configured to wirelessly radiate the transmit RF signal; and a baseband processing circuit including the carrier memory DPD circuit and the peaking memory DPD circuit.
Aspect 16: A method, comprising: applying a first memory predistortion to an input signal to generate a first carrier predistorted signal; applying a second memory predistortion to the input signal to generate a first peaking predistorted signal; generating a carrier radio frequency (RF) signal based on the first carrier predistorted signal; generating a peaking radio frequency (RF) signal based on the first peaking predistorted signal; amplifying the carrier RF signal to generate a carrier transmit RF signal; amplifying the peaking RF signal to generate a peaking transmit RF signal; and combining the carrier transmit RF signal and the peaking transmit RF signal to generate a transmit RF signal.
Aspect 17: The method of aspect 16, wherein: applying the first memory predistortion to the input signal is based on a carrier piecewise linear (PWL) approximation of a gain profile associated with amplifying the carrier RF signal; and applying the second memory predistortion to the input signal is based on a peaking piecewise linear (PWL) approximation of a gain profile associated with amplifying the peaking RF signal.
Aspect 18: The method of aspect 17, wherein: the carrier PWL approximation employs a rectified linear unit (ReLU) function to approximate a set of gain segments of the gain profile associated with amplifying the carrier RF signal; and the peaking PWL approximation employs the ReLU function to approximate a set of gain segments of the gain profile associated with amplifying the peaking RF signal.
Aspect 19: The method of aspect 16 or 17, wherein: applying the first memory predistortion to the input signal is based on a carrier piecewise polynomial (PWP) approximation of a gain profile associated with amplifying the carrier RF signal; and applying the second memory predistortion to the input signal is based on a peaking piecewise polynomial (PWL) approximation of a gain profile associated with amplifying the peaking RF signal.
Aspect 20: The method of aspect 19, wherein: the carrier PWP approximation employs a rectified polynomial function to approximate a set of gain segments of the gain profile associated with amplifying the carrier RF signal; and the peaking PWP approximation employs a rectified polynomial function to approximate a set of gain segments of the gain profile associated with amplifying the peaking RF signal.
Aspect 21: The method of any one of aspects 16-20, further comprising: applying a first memoryless predistortion to the first carrier predistorted signal to generate a second carrier predistorted signal, wherein the carrier RF signal is based on the second carrier predistorted signal; and applying a second memoryless predistortion to the first peaking predistorted signal to generate a second peaking predistorted signal, wherein the peaking RF signal is based on the second peaking predistorted signal.
Aspect 22: The method of aspect 21, further comprising generating a feedback signal based on a portion of the transmit RF signal, wherein applying the first memory predistortion to the input signal is based on the feedback signal, and wherein applying the second memory predistortion to the input signal is based on the feedback signal.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. A transmitter, comprising:
a carrier memory digital predistortion (DPD) circuit configured to predistort an input signal to generate a first carrier predistorted signal;
a peaking memory digital predistortion (DPD) circuit configured to predistort the input signal to generate a first peaking predistorted signal; and
a Doherty amplifier including a carrier power amplifier (CPA) and a peaking power amplifier (PPA), wherein the CPA is configured to generate a carrier transmit radio frequency (RF) signal based on the first carrier predistorted signal, and wherein the PPA is configured to generate a peaking transmit RF signal based on the first peaking predistorted signal.

2. The transmitter of claim 1, wherein the carrier memory DPD circuit is configured to predistort the input signal based on a piecewise linear (PWL) approximation of a gain profile of the CPA.

3. The transmitter of claim 2, wherein the PWL approximation employs a rectified linear unit (ReLU) function that approximates a set of gain segments of the gain profile of the CPA.

4. The transmitter of claim 1, wherein the peaking memory DPD circuit is configured to predistort the input signal based on a piecewise linear (PWL) approximation of a gain profile of the PPA.

5. The transmitter of claim 4, wherein the PWL approximation employs a rectified linear unit (ReLU) function that approximates a set of gain segments of the gain profile of the PPA.

6. The transmitter of claim 1, wherein the carrier memory DPD circuit is configured to predistort the input signal based on a piecewise polynomial (PWP) approximation of a gain profile of the CPA.

7. The transmitter of claim 6, wherein the PWP approximation employs a rectified polynomial function that approximates a set of gain segments of the gain profile of the CPA.

8. The transmitter of claim 1, wherein the peaking memory DPD circuit is configured to predistort the input signal based on a piecewise polynomial (PWP) approximation of a gain profile of the PPA.

9. The transmitter of claim 8, wherein the PWP approximation employs a rectified polynomial function that approximates a set of gain segments of the gain profile of the PPA.

10. The transmitter of claim 1, further comprising:
a carrier memoryless DPD circuit configured to predistort the first carrier predistorted signal to generate a second carrier predistorted signal, wherein the CPA is configured to generate the carrier transmit radio frequency (RF) signal based on the second carrier predistorted signal; and
a peaking memoryless DPD circuit configured to predistort the first peaking predistorted signal to generate a second peaking predistorted signal, wherein the PPA is configured to generate the peaking transmit radio frequency (RF) signal based on the second peaking predistorted signal.

11. The transmitter of claim 10, wherein:
the carrier memoryless DPD circuit is configured to predistort the first carrier predistorted signal based on a carrier lookup table (LUT); and
the peaking memoryless DPD circuit is configured to predistort the first peaking predistorted signal based on a peaking lookup table (LUT).

12. The transmitter of claim 10, further comprising:
a carrier digital-to-analog converter (DAC) configured to convert the second carrier predistorted signal into a carrier analog signal;
a carrier frequency upconverter configured to frequency upconvert the carrier analog signal to generate a carrier radio frequency (RF) signal, wherein the CPA is configured to amplify the carrier RF signal to generate the carrier transmit RF signal;
a peaking digital-to-analog converter (DAC) configured to convert the second peaking predistorted signal into a peaking analog signal; and
a peaking frequency upconverter configured to frequency upconvert the peaking analog signal to generate a peaking radio frequency (RF) signal, wherein the PPA is configured to amplify the peaking RF signal to generate the peaking transmit RF signal.

13. The transmitter of claim 1, further comprising:
a power combiner configured to combine the carrier transmit RF signal and the peaking transmit RF signal to generate a transmit RF signal;
a coupler configured to couple out a portion of the transmit signal to generate a feedback RF signal; and
a feedback chain configured to generate a digital feedback baseband signal based on the feedback RF signal.

14. The transmitter of claim 1, further comprising:
a power combiner configured to combine the carrier transmit RF signal and the peaking transmit RF signal to generate a transmit RF signal;
an antenna configured to wirelessly radiate the transmit RF signal; and
a baseband processing circuit including the carrier memory DPD circuit and the peaking memory DPD circuit.

15. A method of generating a transmit radio frequency (RF) signal, comprising:
applying a first memory predistortion to an input signal to generate a first carrier predistorted signal;
applying a second memory predistortion to the input signal to generate a first peaking predistorted signal;
generating a carrier radio frequency (RF) signal based on the first carrier predistorted signal;
generating a peaking radio frequency (RF) signal based on the first peaking predistorted signal;
amplifying the carrier RF signal to generate a carrier transmit RF signal;
amplifying the peaking RF signal to generate a peaking transmit RF signal; and
combining the carrier transmit RF signal and the peaking transmit RF signal to generate a transmit RF signal.

16. The method of claim 15, wherein:
applying the first memory predistortion to the input signal is based on a carrier piecewise linear (PWL) approximation of a gain profile associated with amplifying the carrier RF signal; and
applying the second memory predistortion to the input signal is based on a peaking piecewise linear (PWL) approximation of a gain profile associated with amplifying the peaking RF signal.

17. The method of claim 16, wherein:
the carrier PWL approximation employs a rectified linear unit (ReLU) function to approximate a set of gain segments of the gain profile associated with amplifying the carrier RF signal; and
the peaking PWL approximation employs the ReLU function to approximate a set of gain segments of the gain profile associated with amplifying the peaking RF signal.

18. The method of claim 15, wherein:
applying the first memory predistortion to the input signal is based on a carrier piecewise polynomial (PWP) approximation of a gain profile associated with amplifying the carrier RF signal; and
applying the second memory predistortion to the input signal is based on a peaking piecewise polynomial (PWL) approximation of a gain profile associated with amplifying the peaking RF signal.

19. The method of claim 18, wherein:
the carrier PWP approximation employs a rectified polynomial function to approximate a set of gain segments of the gain profile associated with amplifying the carrier RF signal; and
the peaking PWP approximation employs a rectified polynomial function to approximate a set of gain segments of the gain profile associated with amplifying the peaking RF signal.

20. The method of claim 15, further comprising:
applying a first memoryless predistortion to the first carrier predistorted signal to generate a second carrier predistorted signal, wherein the carrier RF signal is based on the second carrier predistorted signal; and
applying a second memoryless predistortion to the first peaking predistorted signal to generate a second peaking predistorted signal, wherein the peaking RF signal is based on the second peaking predistorted signal.
